(19) United States
(12) Patent Application Publication
(10) Pub. No.: US 2023/0359019 A1
(43) Pub. Date: Nov. 9, 2023

(54) MICROMECHANICAL RESONATOR WAFER ASSEMBLY AND METHOD OF FABRICATION THEREOF

(71) Applicants: HUAWEI TECHNOLOGIES CO., LTD., Shenzhen (CN); FRAUNHOFER-GESELLSCHAFT ZUR FOERDERUNG DER ANGEWANDTEN FORSCHUNG E.V., Munich (DE)

(72) Inventors: Thomas Knieling, Munich (DE); Ulrich Hofmann, Itzehoe (DE); Stephan Marauska, Itzehoe (DE); Berkan Zorlubas, Itzehoe (DE); Fabian Schwarz, Itzehoe (DE); Frank Senger, Itzehoe (DE); Yong Cao, Munich (DE)

(21) Appl. No.: 18/196,678

(22) Filed: May 12, 2023

Related U.S. Application Data
(63) Continuation of application No. PCT/EP2020/081816, filed on Nov. 12, 2020.

(51) Int. Cl. G02B 26/08; H03H 3/007; H03H 9/10

(52) U.S. Cl. CPC G02B 26/0858; H03H 3/0073; H03H 9/1057

(57) ABSTRACT

A micromechanical resonator wafer assembly includes an actuator wafer supporting an outer actuator layer. The outer actuator layer includes an oscillating part configured to be driven by an electrical drive signal. The micromechanical resonator wafer assembly further includes a device wafer mounted on top of the actuator wafer. The device wafer includes a plurality of inner actuators. Each of the inner actuators include an oscillation body configured to oscillate about one or more axes. The device wafer is physically connected to the actuator wafer such that each of the inner actuators forms with the outer actuator layer a coupled oscillation system for excitation of the oscillation body of the respective inner actuator. The micromechanical resonator wafer assembly provides external actuation of the oscillation body of each of the inner actuators by use of the outer actuator layer and hence, provides improved scan angles with fast start-up time.

### TECHNICAL FIELD

The present disclosure relates generally to the field of micro-electro-mechanical devices;

and more specifically, to a micromechanical resonator wafer assembly and a method of fabricating the micromechanical resonator wafer assembly.

### BACKGROUND

Generally, micro-electro-mechanical system (MEMS) is a technology that is defined in terms of miniaturized mechanical or electromechanical elements which are made of using microfabrication techniques. Typically, physical dimensions of the mechanical or electromechanical elements varies from one micrometre to hundreds of micrometres (100×10⁻⁶).

Typically, a conventional micromechanical resonator (e.g. a conventional micromechanical resonator assembly) include MEMS mirrors which are actuated either by use of internal piezo-electric thin film layers, or electrostatic comb drives, or by magnetic force stimulation. The conventional micromechanical resonator based on aforesaid internal actuation solutions has limited actuation energy and therefore, manifests short scan angles for one dimensional (1D) as well as two dimensional (2D) conventional MEMS mirrors. The reason behind the limited actuation energy is low energy transfer from a conventional actuation structure to the MEMS mirrors of the conventional micromechanical resonator. Moreover, existing micromechanical resonators manifest high-power consumption and slow start-up time, which is not desirable. Thus, there exists a technical problem of an inefficient micromechanical resonator that manifests short scan angles, high power consumption, slow start-up time, and a high manufacturing cost.

Therefore, in light of the foregoing discussion, there exists a need to overcome the aforementioned drawbacks associated with conventional micromechanical resonators and their fabrication.

### SUMMARY

The present disclosure seeks to provide a micromechanical resonator wafer assembly and a method for fabricating the micromechanical resonator wafer assembly. The present disclosure seeks to provide a solution to the existing problem of an inefficient micromechanical resonator that manifests short scan angles, high power consumption, slow start-up time and also a high manufacturing cost (e.g. requires a cost-intensive assembly process for fabrication). An aim of the present disclosure is to provide a solution that overcomes at least partially the problems encountered in prior art and provide an improved and cost-effective micromechanical resonator wafer assembly that has improved scan angles and at the same time manifests low power consumption and fast start-up time as compared to existing micromechanical resonators.

The object of the present disclosure is achieved by the solutions provided in the enclosed independent claims. Advantageous implementations of the present disclosure are further defined in the dependent claims.

In one aspect, the present disclosure provides a micromechanical resonator wafer assembly. The micromechanical resonator wafer assembly comprises an actuator wafer, supporting an outer actuator layer which comprises an oscillating part configured to be driven by an electrical drive signal. The micromechanical resonator wafer assembly further comprises a device wafer mounted on top of the actuator wafer, comprising a plurality of inner actuators, each of said inner actuators including an oscillation body configured to oscillate about one or more axes, the oscillation of the oscillation body having one or more eigenfrequencies. The device wafer is physically connected to the actuator wafer such that each of the inner actuators forms with the outer actuator layer a coupled oscillation system for excitation of the oscillation body of the respective inner actuator by transfer of energy from the oscillating part to the oscillating body when the oscillating part of the outer actuator layer is activated with a frequency selected to excite resonant or near-resonant oscillation of the oscillation body of the inner actuator.

The micromechanical resonator wafer assembly is capable of achieving large scan angles at low power consumption as compared to a conventional micromechanical resonator. For example, large scan angles up to 180° for one-dimensional (1D) and larger than 100°×100° for two-dimensional (2D) oscillation body is achieved by the disclosed micromechanical resonator wafer assembly at low power consumption in milliwatt range with improved start-up time (e.g. less than 1 second). In contrast to conventional micromechanical resonators, the micromechanical resonator wafer assembly has the outer actuator layer, and when the oscillating part of the outer actuator layer is activated, a high energy transfer from the oscillating part to the oscillation body of the corresponding inner actuator is achieved. This enables the micromechanical resonator wafer assembly to achieve large scan angles at low power consumption as compared to existing micromechanical resonators. Moreover, the disclosed micromechanical resonator wafer assembly is cost-effective because of its low complexity in fabrication.

In an implementation form, the device wafer is bounded together with the actuator wafer.

The device wafer is bounded with the actuator wafer, which simplifies the fabrication process, and makes possible high-volume fabrication of multiple micromechanical resonator assemblies in parallel, thereby reducing the overall cost and improving the product quality (e.g. robustness) of micromechanical resonator wafer assembly.

In a further implementation form, the micromechanical resonator wafer assembly further comprises a cap wafer bounded on top of the device wafer and comprising at least one optical window.

The cap wafer is placed above the device wafer to form a sealed vacuum cavity for low air damping operation of the oscillation body. Further, the cap wafer provides environmental protection to various components of the micromechanical resonator wafer assembly, for example, protection from dirt and moisture. The optical window provides a cavity for efficient movement of the oscillation body encapsulated within the micromechanical resonator wafer assembly.

In a further implementation form, the optical window is 3D-shaped.

By the virtue of 3D-shape of the optical window, an efficient movement as well as environmental protection of the oscillation body is ensured.

In a further implementation form, the micromechanical resonator wafer assembly further comprises a spacer wafer bounded between the actuator wafer and the device wafer.

In this case, the spacer wafer (may also be referred as a distance holder wafer) increases distance between the device wafer and actuator wafer for enhanced friction-free movement of the oscillation body. In particular, the spacer prevents the oscillation body from hitting the wafer assembly, thus avoiding mechanical shocks while oscillating, especially in case of large oscillation amplitude.

In a further implementation form, each of the inner actuators comprises an internal sensor configured to allow reading out of a position feedback signal of its oscillation body by driving means.

The internal sensor allows the driving means to read out the position feedback signal of the oscillation body in order to drive a stable amplitude operation of the oscillation body.

In a further implementation form, the outer actuator layer is a piezoelectric layer, with patterned metallic electrodes configurated to face a corresponding inner actuator in the device wafer and to be connected to a driving part to receive an electrical drive signal.

By virtue of the electrical connection between the outer actuator layer and the driving part, the electrical drive signal is applied to the piezoelectric layer. The piezoelectric layer does a mechanical movement (e.g. a bending mode vibration) on applying the electrical drive signal and further actuates the oscillation body to oscillate about its axis.

In a further implementation form, the outer actuator layer is a stacked piezoelectric structure comprising a bottom layer including one or more bottom patterned electrodes, a piezoelectric layer on top of the bottom layer, and a top layer on top of the piezoelectric layer and including one or more top patterned electrodes.

The stacked piezoelectric structure of the outer actuator layer performs a movement or vibration on applying an electrical drive signal. The movement or vibration of the stacked piezoelectric structure transfers a mechanical energy (i.e. an actuation energy) in the form of the movement or vibration to the oscillation body and actuates the oscillation body to oscillate about its axis. Additionally, the stacked piezoelectric structure provides a robust micromechanical resonator assembly and easy handling when in operation.

In a further implementation form, the outer actuator layer comprises a sequence of alternating piezoelectric layers and passive layers, with at least one piezoelectric layer and at least one passive layer.

By virtue of the sequence of alternating piezoelectric layers and passive layers, the outer actuator layer is capable of performing bending motion to actuate the oscillation body.

In a further implementation form, the actuator wafer comprises a ceramic substrate with patterned piezoelectric areas.

The actuator wafer comprises the ceramic substrate, which has excellent heat resistance, high mechanical strength and provides a lower cost option for developing the actuator wafer. Further, the patterned piezoelectric areas are provided to actuate the oscillation body when the patterned piezoelectric areas are coupled to the electrical drive signal.

In a further implementation form, the patterned piezoelectric areas are stacked piezoelectric areas comprising a bottom electrode, a piezoelectric layer on top of the bottom electrode, and a top electrode on top of the piezoelectric layer.

By virtue of the stacked piezoelectric areas, the patterned piezoelectric areas are capable of performing a bending motion which further actuates the oscillation body.

In a further implementation form, the oscillation body of each of the inner actuators comprises a wafer-level vacuum encapsulated spring-mirror plate system.

The oscillation body of each of the inner actuators comprises the wafer-level vacuum encapsulated spring-mirror plate system in order to reduce an air damping effect while simultaneously results into a high-quality factor (Q factor) of the micromechanical resonator wafer assembly.

In another aspect, the present disclosure provides a light engine for laser scanning or laser projection system comprising at least one micromechanical resonator assembly obtained by singulation of the micromechanical resonator wafer assembly.

The light engine enables to control deflection of laser rays to project appropriate image on a display area, such as a human eye. The light engine comprises at least one micromechanical resonator assembly that allows the laser scanning or laser projection system to achieve increased scan angle with low power consumption. Further, laser scanning or laser projection system has reduced start-up time and is cost efficient with robust quality.

In an implementation form, the laser projection or laser scanning system comprising the light engine, such as AR or VR glasses or helmet, or a Lidar system.

The laser projection or laser scanning system comprising the light engine finds application in augmented reality (AR) or virtual reality (VR) glasses or helmet, or the light detection and ranging (LiDAR) system, which provides extremely large scan angles that is from 110° to 180° and extremely fast start-up time that is less than 1s.

In a yet another aspect, the present disclosure provides a method of fabricating a micromechanical resonator wafer assembly. The method comprises an actuator wafer, supporting an outer actuator layer which comprises an oscillating part configured to be driven by an electrical drive signal. The method further comprises a device wafer mounted on top of the actuator wafer, comprising a plurality of inner actuators, each of which including an oscillation body configured to oscillate about one or more axis. The method further comprises physically connecting the device wafer together with the actuator wafer such that each of the inner actuators forms with the outer actuator layer a coupled oscillation system for excitation of the corresponding oscillation body by transfer of energy from the oscillating part to said corresponding oscillating body.

The method of fabricating the micromechanical resonator wafer assembly is cost-effective and results in an improved actuation geometry in the micromechanical resonator wafer assembly. In other words, the micromechanical resonator wafer assembly fabricated by use of the presented method achieves extremely large scan angles, for example, up to 180° and extremely fast start-up time which is less than 1s with low power consumption. Moreover, the method of fabricating the micromechanical resonator wafer assembly of the aspect achieves all the advantages and effects of the micromechanical resonator wafer assembly.

In an implementation form, the method further comprises physically connecting the device wafer with the actuator wafer comprises bounding said device wafer together with said actuator wafer.

The bounding of the device wafer together with the actuator wafer simplifies the fabrication process and makes possible high-volume fabrication of multiple micromechanical resonator assemblies in parallel, thereby reducing the overall cost and improving the product quality (e.g. robustness) of micromechanical resonator wafer assembly.

In a further implementation form, the method further comprises bounding a cap wafer on top of the device wafer, said cap wafer comprising at least one optical window.

The bounding of the cap wafer on top of the device wafer forms a sealed vacuum cavity for low air damping operation of the oscillation body.

In a further implementation form, the optical window is 3D-shaped.

By the virtue of 3D-shape of the optical window, a cavity is formed for efficient movement of the oscillation body.

In a further implementation form, the method further comprises bounding a spacer wafer between the actuator wafer and the device wafer.

The spacer wafer (may also be referred as a distance holder wafer) increases distance between the device wafer and actuator wafer for enhanced friction-free movement of the oscillation body. In particular, the spacer prevents the oscillation body from hitting the wafer assembly, thus avoiding mechanical shocks while oscillating, especially in case of large oscillation amplitude.

In a further implementation form, the oscillation body of each of the inner actuators comprises a wafer-level vacuum encapsulated spring-mirror plate system.

The oscillation body of each the inner actuators comprises the wafer-level vacuum encapsulated spring-mirror plate system in order to reduce an air damping effect and results into a high-quality factor (Q factor) of the micromechanical resonator wafer assembly.

It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1A is an exemplary illustration of a micromechanical resonator wafer assembly, in accordance with an embodiment of the present disclosure;

FIG. 1B is an exemplary illustration of a plurality of micromechanical resonator assemblies derived from the micromechanical resonator wafer assembly of FIG. 1A, in accordance with another embodiment of the present disclosure;

FIG. 1C is an exemplary illustration of an oscillatory movement of the oscillation body of the first micromechanical resonator assembly of FIG. 1B, in accordance with an embodiment of the present disclosure;

FIG. 2 is an exemplary illustration of a plurality of micromechanical resonator assemblies derived from a micromechanical resonator wafer assembly, in accordance with another embodiment of the present disclosure;

FIG. 3 is an exemplary illustration of a laser scanning or a laser projection system, in accordance with an embodiment of the present disclosure; and

FIG. 4 is a flowchart of a method of fabricating a micromechanical resonator wafer assembly, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

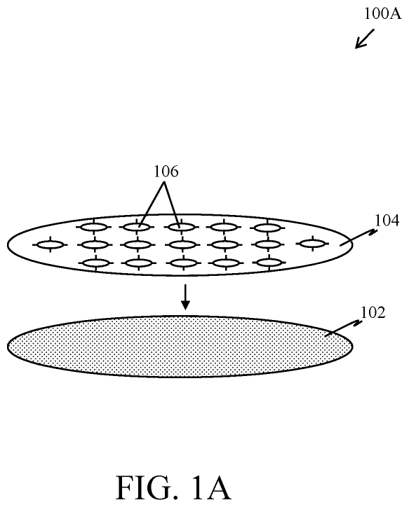

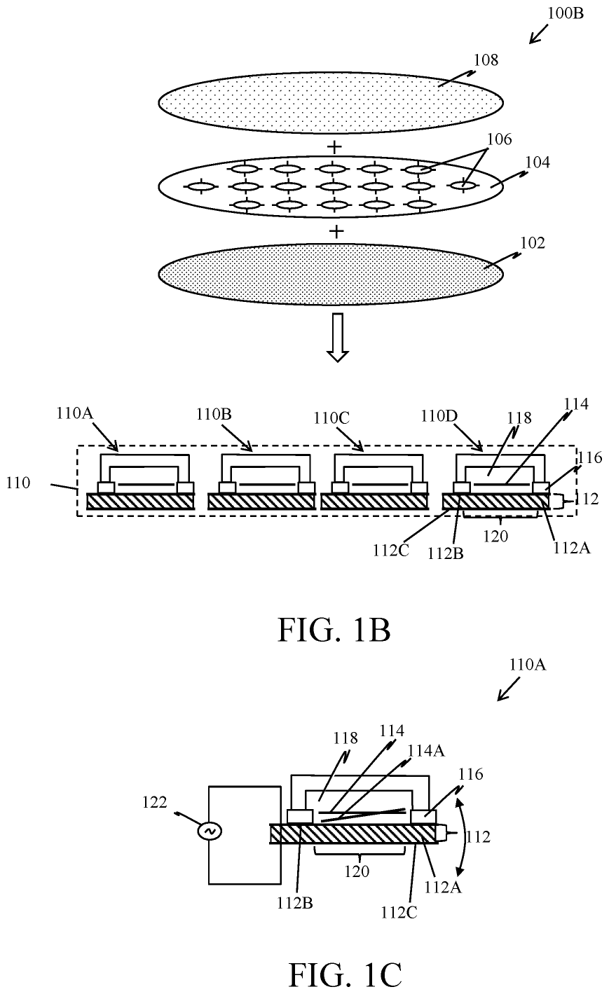

FIG. 1A is an exemplary illustration of a micromechanical resonator wafer assembly, in accordance with an embodiment of the present disclosure. With reference to FIG. 1A, there is shown a micromechanical resonator wafer assembly 100A. The micromechanical resonator wafer assembly 100A comprises an actuator wafer 102 and a device wafer 104. The device wafer 104 comprises a plurality of inner actuators 106.

The micromechanical resonator wafer assembly 100A is a two-level wafer stack where one wafer level is bonded to the other wafer level by use of a wafer level packaging technique. The two-level wafer stack of the micromechanical resonator wafer assembly 100A is diced or sawn in order to obtain a plurality of micromechanical resonators or a plurality of micromechanical resonator assemblies. In another embodiment, the micromechanical resonator wafer assembly 100A may refers to a three-level wafer stack. The plurality of micromechanical resonators obtained by dicing or sawing of the micromechanical resonator wafer assembly 100A are used in light projection systems. Examples of such light projection systems include, but are not limited to a laser projection system, a laser scanning system, light detection and ranging (LiDAR) system, Augmented Reality (AR) and Virtual Reality (VR) based glasses, helmets, and the like.

The actuator wafer 102 comprises stacked piezo structures which are made up of, for example, lead zirconate titanate (PZT), aluminium nitride (AlN), aluminium scandium nitride (AlScN) or other ferroelectric material. The stacked piezo structures of the actuator wafer 102 are configured to perform a bending mode vibration. The bending mode vibration refers to a bending motion that is caused when an electric signal (e.g. a voltage or a current signal) is applied to the stacked piezo structures which are comprised by the actuator wafer 102.

The device wafer 104 comprises the plurality of inner actuators 106. The device wafer 104 is mounted on top of the actuator wafer 102 to form the two-level wafer stack of the micromechanical resonator wafer assembly 100A.

The plurality of inner actuators 106 may also be referred as micro mirrors elements or micro mirror dies. The plurality of inner actuators 106 is configured to transfer an actuation energy (e.g. an electrical or a mechanical energy) from the actuator wafer 102 to an oscillation body (not shown here) which is comprised by each of the plurality of inner actuators 106. The actuation energy excites the one or more eigen frequencies of the oscillation body and causes the oscillation body to oscillate about its axis. The plurality of inner actuators 106 may also be referred as piezoelectric actuators or electrostatic actuators.

FIG. 1B is an exemplary illustration of a plurality of micromechanical resonator assemblies derived from the micromechanical resonator wafer assembly of FIG. 1A, in accordance with an embodiment of the present disclosure. FIG. 1B is described in conjunction with elements from FIG. 1A. With reference to FIG. 1B, there is shown an exemplary illustration 100B of a plurality of micromechanical resonator assemblies derived from the micromechanical resonator wafer assembly 100A of FIG. 1A. There is further shown a cap wafer 108, a plurality of micromechanical resonator assemblies 110 that includes a first micromechanical resonator assembly 110A, a second micromechanical resonator assembly 110B, a third micromechanical resonator assembly 110C and a fourth micromechanical resonator assembly 110D. Each of the plurality of micromechanical resonator assemblies 110 comprises an outer actuator layer 112, an oscillation body 114, a micro mirror die 116 and a hermetic vacuum encapsulated cavity 118. The outer actuator layer 112 comprises a piezoelectric layer 112A, a top layer 112B, a bottom layer 112C and an oscillating part 120.

In an implementation, the micromechanical resonator wafer assembly 100A includes the actuator wafer 102, the device wafer 104 and additionally, the cap wafer 108. The cap wafer 108 is placed above the device wafer 104 to form a sealed vacuum cavity for low air damping operation of the oscillation body 114. Further, the cap wafer 108 provides environmental protection to various components of the plurality of micromechanical resonator assemblies 110 such as protection from dirt and moisture. The cap wafer 108 may also be referred as a glass wafer.

The micromechanical resonator wafer assembly 100A undergoes a singulation process to form the plurality of micromechanical resonator assemblies 110. The singulation process may also be referred as dicing or sawing. The singulation process is a process of reducing the micromechanical resonator wafer assembly 100A to the plurality of micromechanical resonator assemblies 110. The plurality of micromechanical resonator assemblies 110 comprises the first micromechanical resonator assembly 110A, the second micromechanical resonator assembly 110B, the third micromechanical resonator assembly 110C and the fourth micromechanical resonator assembly 110D.

In the micromechanical resonator wafer assembly 100A, the actuator wafer 102 is configured to support the outer actuator layer 112 which comprises the oscillating part 120 configured to be driven by an electrical drive signal. When the electrical drive signal is applied to the outer actuator layer 112, the oscillating part 120 performs various mechanical movements, for example, a bending mode vibration. The reason behind this is that the outer actuator layer 112 comprises a piezoelectric layer which is stacked in between patterned metallic electrodes. Therefore, the oscillating part 120 performs the bending mode vibration by virtue of the piezoelectric layer.

The device wafer 104 mounted on top of the actuator wafer 102, comprising the plurality of inner actuators 106. Each of the inner actuators 106 includes the oscillation body 114 which is configured to oscillate about one or more axes, the oscillation body 114 having one or more eigen frequencies. The bending mode vibration (i.e. the mechanical movement) of the oscillating part 120 of the outer actuator layer 112 translates into a vibration of the plurality of inner actuators 106 which further results into an oscillatory movement of the oscillation body 114. The vibration of the plurality of inner actuators 106 transfers a vibration energy (or actuation energy) to the oscillation body 114 and excites the oscillation body 114 to oscillate about its axis. The oscillation body 114 is configured to oscillate about one or more axes and hence, have one or more eigen frequencies. In an example, the oscillation body 114 may oscillate about an axis to perform an oscillatory rotative motion about the axis. In another example, the oscillation body 114 may oscillate about two axes, for example, a first axis and a second axis and both axes are perpendicular to each other. The oscillation body 114 may also be referred as a mirror plate or a mirror plate spring system (that is defined as a mirror plate mounted on a spring).

The device wafer 104 is physically connected to the actuator wafer 102 such that each of the inner actuators 106 forms with the outer actuator layer 112 a coupled oscillation system for excitation of the oscillation body 114 of the respective inner actuator 106 by transfer of energy from the oscillating part 120 to the oscillation body 114 when the oscillating part 120 of the outer actuator layer 112 is activated with a frequency selected to excite resonant or near-resonant oscillation of the oscillation body 114 of the inner actuator 106. When the electrical drive signal (i.e. the voltage or the current signal) of the selected frequency is applied to the outer actuator layer 112, the oscillating part 120 performs the bending mode vibration which in turn results into vibration of the plurality of inner actuators 106. Thus, the plurality of inner actuators 106 (or the micro mirror dies) and oscillating part 120 of the outer actuator layer 112 forms the coupled oscillation system. The coupled oscillation system excites the resonant or near-resonant oscillations of the oscillation body 114 by virtue of transfer of the vibration energy from the oscillating part 120 to the oscillation body 114. The frequency of electrical drive signal applied to the outer actuator layer 112 is chosen in such a way that the oscillation body 114 oscillates at its resonant frequency or near its resonant frequency (i.e. eigen frequency). The oscillation body 114 that oscillates at its resonant or near-resonant frequency obtains increased oscillation amplitude and thus, results in large scan angle with low power consumption.

In accordance with an embodiment, the device wafer 104 is bonded together with the actuator wafer 102. The device wafer 104 is bonded on the top of the actuator wafer 102 by use of various wafer bonding methods such as anodic bonding, glass frit bonding, etc. The bonded stack refers to the two-level wafer stack of the micromechanical resonator wafer assembly 100A which is further diced or sawn into single mirror modules such as the plurality of micromechanical resonator assemblies 110.

In accordance with an embodiment, the micromechanical resonator wafer assembly 100A further comprises the cap wafer 108 bonded on top of the device wafer 104 and comprising at least one optical window. The cap wafer 108 is placed on top of the device wafer 104 to form a three-level wafer stack of the micromechanical resonator wafer assembly 100A. The three-level wafer stack comprises the device wafer 104 on top of the actuator wafer 102 and the cap wafer 108 on top of the device wafer 104. The cap wafer 108 is bonded on top of the device wafer 104 by use of various wafer bonding methods such as anodic bonding, glass frit bonding, and the like. The cap wafer 108 comprises the at least one optical window which provides a cavity for efficient movement of the oscillation body 114 encapsulated within the micromechanical resonator wafer assembly 100A.

In accordance with an embodiment, the optical window is 3D-shaped. In an implementation, the cap wafer 108 may refer to a three-dimensional (3-D shaped) glass wafer. In such implementation, the optical window is either tilted or has a dome like shape.

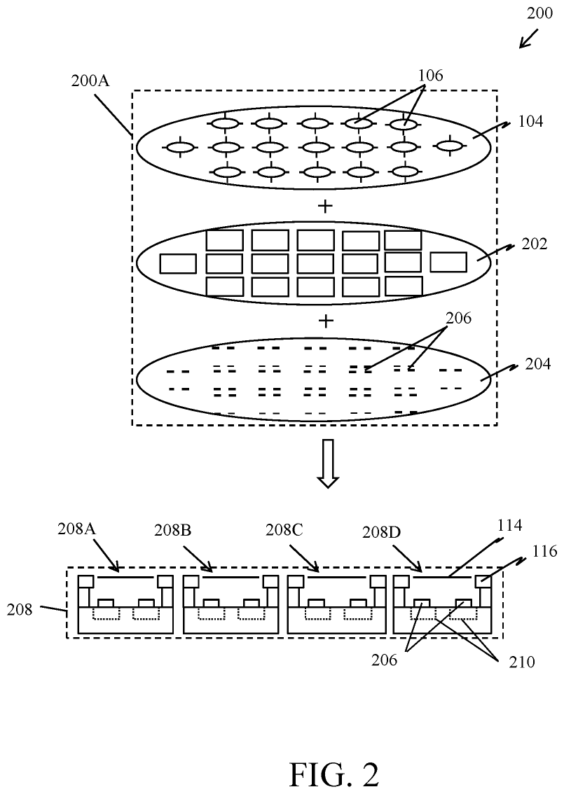

In an embodiment, the micromechanical resonator wafer assembly 100A further comprises a spacer wafer bonded between the actuator wafer 102 and the device wafer 104. An exemplary implementation of the spacer wafer bonded between the actuator wafer 102 and the device wafer 104 is described in detail, for example, in FIG. 2. The spacer wafer bonded between actuator wafer 102 and the device wafer 104 forms a three-level wafer stack by use of various wafer bonding methods such as anodic bonding, glass frit bonding, and the like.

In accordance with an embodiment, each of the inner actuators 106 comprises an internal sensor configured to allow reading out of a position feedback signal of its oscillation body 114 by driving means. The internal sensor allows the driving means to read out the position feedback signal of the oscillation body 114. The position feedback signal of the oscillation body 114 is applied in a closed loop in order to control the oscillations of the oscillation body 114. This results into a stable amplitude operation of the oscillation body 114. Examples of the driving means may include, but not limited to electronic components such as an amplifier, a capacitor, an inductor, a resistor, and the like.

In accordance with an embodiment, the outer actuator layer 112 is a piezoelectric layer, with patterned metallic electrodes configurated to face a corresponding inner actuator 106 in the device wafer 104 and to be connected to a driving part to receive an electrical drive signal. In an implementation, the outer actuator layer 112 is a piezoelectric layer with patterned metallic electrodes. The outer actuator layer 112 (i.e. the piezoelectric layer) is connected to the corresponding inner actuator 106 at one end and to the driving part at another end. The electrical drive signal is applied to the outer actuator layer 112 by virtue of the electrical connection between the driving part and the outer actuator layer 112. Therefore, the outer actuator layer 112 being the piezoelectric layer performs a mechanical movement, for example, a bending mode vibration. The vibration energy produced in this way is transferred to the corresponding inner actuator 106 (or the micro mirror die) through the connection between the outer actuator layer 112 and the corresponding inner actuator 106. This further results into an oscillatory movement of the oscillation body 114 (or the mirror plate spring system).

In accordance with an embodiment, the outer actuator layer 112 is a stacked piezoelectric structure comprising a bottom layer 112C including one or more bottom patterned electrodes, a piezoelectric layer 112A on top of the bottom layer 112C, and a top layer 112B on top of the piezoelectric layer 112A and including one or more top patterned electrodes. In another implementation, the outer actuator layer 112 may be a stacked piezoelectric structure. The stacked piezoelectric structure comprises the piezoelectric layer 112A placed between the bottom layer 112C and the top layer 112B. Further, the bottom layer 112C and the top layer 112B includes patterned electrodes. The materials used for the piezoelectric layer 112A may include, but are not limited to lead zirconate titanate (PZT), aluminium nitride (AlN), aluminium scandium nitride (AlScN), or other ferroelectric material.

In accordance with an embodiment, the outer actuator layer 112 comprises a sequence of alternating piezoelectric layers and passive layers, with at least one piezoelectric layer and at least one passive layer. In another implementation, the outer actuator layer 112 may have a sequence of alternating piezoelectric layers and passive layers (i.e. non-piezoelectric layers) to form a bi-morph structure, or a tri-morph structure or a multilayer structure. The bi-morph structure of the outer actuator layer 112 comprises one piezoelectric layer and one passive layer. The tri-morph structure of the outer actuator layer 112 comprises two piezoelectric layers and one passive layer which are arranged such that the passive layer is placed between the two piezoelectric layers. The multilayer structure of the outer actuator layer 112 comprises multiple piezoelectric layers and multiple passive layers arranged in alternating sequence. In this way, the outer actuator layer 112 may have different configurations which are related to either geometry or piezoelectric polarization. Thus, the outer actuator layer 112 performs different mechanical movements on applying the electrical drive signal because of the different configurations.

In accordance with an embodiment, the actuator wafer 102 comprises a ceramic substrate with patterned piezoelectric areas. An exemplary implementation of the actuator wafer 102 comprising the ceramic substrate with patterned piezoelectric areas is described in detail, for example, in FIG. 2.

In accordance with an embodiment, the patterned piezoelectric areas are stacked piezoelectric areas comprising a bottom electrode, a piezoelectric layer on top of the bottom electrode, and a top electrode on top of the piezoelectric layer. An exemplary implementation of the patterned piezoelectric areas as stacked piezoelectric areas comprising the bottom electrode, the piezoelectric layer and the top electrode is described in detail, for example, in FIG. 2.

In accordance with an embodiment, the oscillation body 114 of each of the inner actuators 106 comprises a wafer-level vacuum encapsulated spring-mirror plate system. The wafer-level vacuum encapsulated spring-mirror plate system reduces the air damping effects and results into high quality factor (Q factor) of the micromechanical resonator wafer assembly 100A.

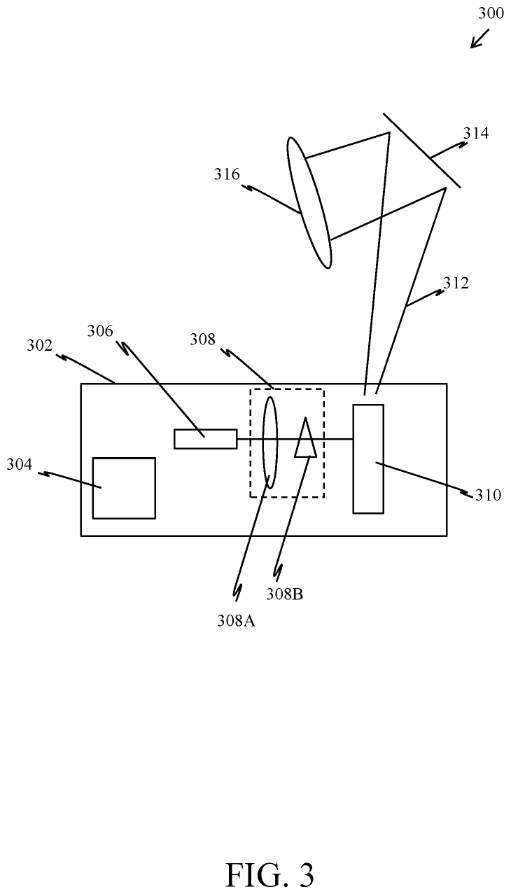

In accordance with an embodiment, one or more of the plurality of micromechanical resonator assemblies 110 may be used in a light engine for laser scanning or laser projection system. An exemplary implementation of the light engine for laser scanning or laser projection system comprising one or more of the plurality of micromechanical resonator assemblies 110 is described in detail, for example, in FIG. 3.

In accordance with an embodiment, a laser projection or scanning system comprising the light engine, such as AR/VR glasses or helmet, or a Lidar system. Examples of the laser projection or scanning system comprising the light engine include augmented reality (AR) or virtual reality (VR) glasses or helmets, light detection and ranging (LiDAR) system and the like. The light engine comprises one or more of the plurality of micromechanical resonator assemblies 110 in order to project light at a certain angle on requirement basis. These systems provide extremely large scan angles up to 180° and extremely fast start-up time that is less than 1s. Additionally, the laser projection or scanning system comprising the light engine operates at a low power consumption and has a robust quality.

FIG. 1C is an exemplary illustration of an oscillatory movement of the oscillation body of the first micromechanical resonator assembly of FIG. 1B, in accordance with an embodiment of the present disclosure. FIG. 1C is described in conjunction with elements from FIGS. 1A and 1B. With reference to FIG. 1C, there is shown the first micromechanical resonator assembly 110A which is connected to an electrical drive signal 122.

When the electrical drive signal 122 is applied to the outer actuator layer 112 by use of the electrical driving means, the oscillating part 120 performs a bending mode vibration (an up-down bending motion) which is indicated by a double-sided arrow. The oscillatory part 120 performs the bending mode vibration by virtue of the piezo electric layer (or the stacked piezo structures) which is comprised by the outer actuator layer 112. The bending mode vibration of the oscillatory part 120 translates into vibration of the micro mirror die 116. The vibration of the micro mirror die 116 results in an oscillatory movement of the oscillation body 114 to a position 114A. The position 114A refers to an oscillatory tilting of the oscillation body 114 (or the mirror plate spring system).

FIG. 2 is an exemplary illustration of a plurality of micromechanical resonator assemblies derived from a micromechanical resonator wafer assembly, in accordance with another embodiment of the present disclosure. FIG. 2 is described in conjunction with elements from FIGS. 1A, 1B, and 1C. With reference to FIG. 2, there is shown an exemplary illustration 200 of a plurality of micromechanical resonator assemblies derived from a micromechanical resonator wafer assembly 200A. The micromechanical resonator wafer assembly 200A includes the device wafer 104 (of FIG. 1A), a spacer wafer 202 and an actuator wafer 204. The actuator wafer 204 includes patterned piezoelectric areas 206. There is further shown a plurality of micromechanical resonator assemblies 208 that includes a first micromechanical resonator assembly 208A, a second micromechanical resonator assembly 208B, a third micromechanical resonator assembly 208C and a fourth micromechanical resonator assembly 208D. Each of the plurality of micromechanical resonator assemblies 208 comprises the oscillation body 114, the micro mirror die 116, patterned piezoelectric areas 206 and optional cavity 210.

The spacer wafer 202 (also referred as a distance holder wafer) provides distance between the device wafer 104 and the actuator wafer 204 for enhanced friction-free movement of the oscillation body 114. In particular, the spacer wafer 202 prevents the oscillation body 114 from hitting the wafer assembly, thus avoiding mechanical shocks while oscillating, especially in case of large oscillation amplitude. The spacer wafer 202, the device wafer 104 and the actuator wafer 204 are aligned such that the device wafer 104 is bonded on top of the spacer wafer 202 and the spacer wafer 202 is arranged on top of the actuator wafer 204. The spacer wafer 202 is bonded with the device wafer 104 and the actuator wafer 204 to form a three-level wafer stack of the micromechanical resonator wafer assembly 200A. The three-level wafer stack of the micromechanical resonator wafer assembly 200A is bonded together using wafer bonding methods that may include, but are not limited to anodic bonding, glass frit bonding and the like.

The actuator wafer 204 comprises the ceramic substrate with patterned piezoelectric areas 206. The ceramic substrate manifests heat resistance, high mechanical strength and lower cost for developing the actuator wafer 204. The patterned piezoelectric areas 206 are stacked piezoelectric areas comprising a bottom electrode, a piezoelectric layer on top of the bottom electrode, and a top electrode on top of the piezoelectric layer. The patterned piezoelectric areas 206 are pre-processed by deposition and etching steps. The materials used for the piezoelectric layer may include, but are not limited to lead zirconate titanate (PZT), aluminium nitride (AlN), aluminium scandium nitride (AlScN), or other ferroelectric material. The materials used for the top electrode and the bottom electrode may include, but are not limited to copper, aluminium, tungsten, and the like.

The three-level wafer stack of the micromechanical resonator wafer assembly 200A is diced into the plurality of micromechanical resonator assemblies 208 that includes the first micromechanical resonator assembly 208A, the second micromechanical resonator assembly 208B, the third micromechanical resonator assembly 208C and the fourth micromechanical resonator assembly 208D. Alternatively, sawing can also be used to separate the wafers of the micromechanical resonator wafer assembly 200A. In an implementation, the device wafer 104 may be sawn into multiple mirror chips thereafter each mirror chip is transferred or bonded to the ceramic substrate of the actuator wafer 204.

Each of the plurality of micromechanical resonator assemblies 208 comprises the optional cavity 210 which is used to provide free standing structures of the patterned piezoelectric areas 206 of the actuator wafer 204.

In operation, when an electrical drive signal (e.g. a voltage or a current signal) is applied to the actuator wafer 204, the electrical drive signal leads to a movement of the patterned piezoelectric areas 206. The movement of the patterned piezoelectric areas 206 may be an elongation and contraction movement if the patterned piezoelectric areas 206 are clamped structures or a bending movement if the patterned piezoelectric areas 206 are free standing structures. In this embodiment, the patterned piezoelectric areas 206 are used as free-standing structures by virtue of the optional cavity 210 and hence, perform the bending movement. The bending movement of the patterned piezoelectric areas 206 leads to transfer of a vibration energy to the micro mirror die 116 which further results into an oscillatory movement of the oscillation body 114 of each of the plurality of micromechanical resonator assemblies 208.

FIG. 3 is an illustration of an exemplary implementation of a micromechanical resonator assembly in a laser scanning or laser projection system, in accordance with an embodiment of the present disclosure. FIG. 3 is described in conjunction with elements from FIGS. 1A, 1B, 1C, and 2. With reference to FIG. 3, there is shown a laser projection system 300 that includes a light engine 302. The light engine 302 further includes a microcontroller 304, a red-green-blue (RGB) laser 306, a plurality of optical elements 308, and a micromechanical resonator assembly 310. There is further shown a plurality of projected rays 312, a reflection surface 314 and a human eye 316. The plurality of optical elements 308 includes an optical lens 308A and a prism 308B

The laser projection system 300 (or a laser projector) is configured to project a laser beam on a screen in order to create a moving image either for entertainment or a professional use. The laser projection system 300 uses the RGB laser 306 and therefore, creates a coloured image on the screen. The laser projection system 300 is used in head-up display projection, laser headlights, active scene or object lightning, projection of information, for laser scanning in a light detection and ranging (LiDAR) system, laser projection in augmented reality (AR)/virtual reality (VR) glasses or helmets, and the like.

The light engine 302 is configured to control the intensity (or brightness) of the created image, colour of the image, projection angle of the image and resolution of the image by use of a control circuitry such as the microcontroller 304, the plurality of optical elements 308 and the micromechanical resonator assembly 310. The light engine 302 is based on an optical micro-electro-mechanical (MEM) technology which uses a micro-mirror device (such as the micromechanical resonator assembly 310).

The microcontroller 304 (also represented as μC) is configured to control functioning of all the components of the light engine 302 such as the RGB laser 306, the plurality of optical elements 308 and the micromechanical resonator assembly 310. The microcontroller 304 (i.e. μC) controls a light coming from a light source and provides the controlled light to the RGB laser 306.

The RGB laser 306 is configured to produce a coloured image on the screen. The different colours of the RGB laser 306 that is red, green and blue get combined into each other in a certain ratio in order to produce various colours of the image.

The optical lens 308A of the plurality of optical elements 308 is configured to focus the RGB lights from the RGB laser 306 to the prism 308B. The prism 308B is configured to receive the focused lights from the optical lens 308A and provides it to the micromechanical resonator assembly 310. In this way, the plurality of optical elements 308 are used to focus the lights from the RGB laser 306 to the micromechanical resonator assembly 310.

In an implementation, the micromechanical resonator assembly 310 corresponds to one or more of the plurality of micromechanical resonator assemblies 110 (of FIG. 1B) that is obtained by singulation of the micromechanical resonator wafer assembly 100A (of FIG. 1A). In another implementation, the micromechanical resonator assembly 310 corresponds to one or more of the plurality of micromechanical resonator assemblies 208 (of FIG. 2) that is obtained by singulation of the micromechanical resonator wafer assembly 200A (of FIG. 2). The micromechanical resonator assembly 310 is configured to project the received focused light from the plurality of optical elements 308 to the reflection surface 314 by use of the plurality of projected rays 312. The micromechanical resonator assembly 310 is configured to produce an image with high resolution since each mirror of the micromechanical resonator assembly 310 is configured to create one or more pixels of the produced image. The micromechanical resonator assembly 310 may also be referred as a MEMS mirror with external piezo mounting. In another implementation, the micromechanical resonator assembly 310 may include an array of micro-mirrors.

The plurality of projected rays 312 get reflected from the reflection surface 314 (e.g. reflection surface of google glass) and may enter the human eye 316 (when viewed). Due to the reflection of the plurality of projected rays 312 from the reflection surface 314, a coloured and moving image become visible to the human eye 316.

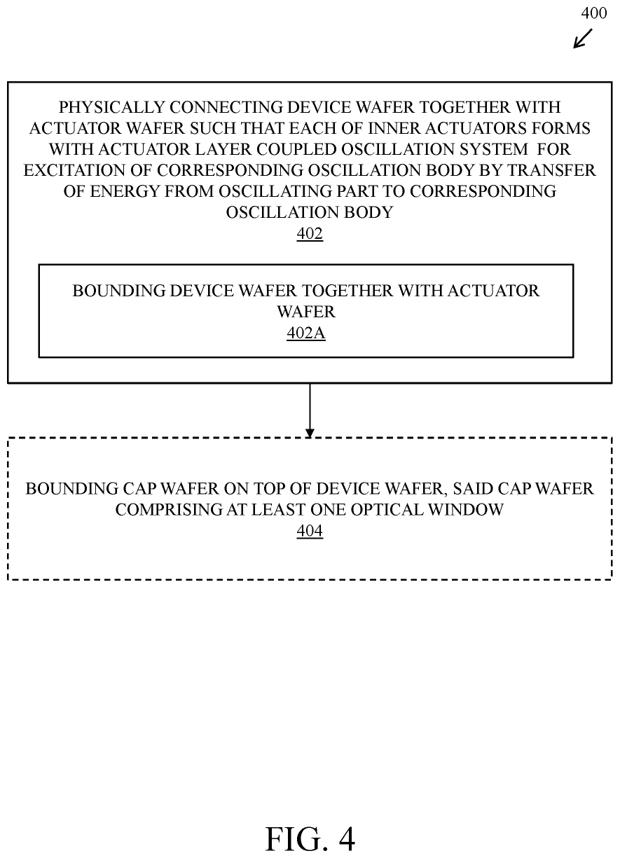

FIG. 4 is a flowchart of a method of fabricating a micromechanical resonator wafer assembly, in accordance with an embodiment of the present disclosure. FIG. 4 is described in conjunction with elements from FIGS. 1A, 1B, 1C, and 2. With reference to FIG. 4, there is shown a method 400 of fabricating a micromechanical resonator wafer assembly such as the micromechanical resonator wafer assembly 100A of FIG. 1A. The method 400 is executed, for example, by the micromechanical resonator wafer assembly 100A (of FIG. 1A). The method 400 include steps 402 and 404.

The micromechanical resonator wafer assembly 100A of FIG. 1A comprises the actuator wafer 102 and the device wafer 104. The actuator wafer 102 supports the outer actuator layer 112 which comprises the oscillating part 120 configured to be driven by an electrical drive signal. The device wafer 104 is mounted on top of the actuator wafer 102. The device wafer 104 comprises the plurality of inner actuators 106, each of which including the oscillation body 114 configured to oscillate about one or more axis.

At step 402, the method 400 comprises physically connecting the device wafer 104 together with the actuator wafer 102 such that each of the inner actuators 106 forms with the outer actuator layer 112 a coupled oscillation system for excitation of the corresponding oscillation body 114 by transfer of energy from the oscillating part 120 to the corresponding oscillation body 114. The device wafer 104 is bonded on top of the actuator wafer 102 to form the micromechanical resonator wafer assembly 100A. The device wafer 104 is connected with the actuator wafer 102 such that when the outer actuator layer 112 is connected to the electrical drive signal by use of the electrical driving means, a movement of the oscillating part 120 of the outer actuator layer 112 translates into a vibration motion of the micro mirror die 116 of the device wafer 104. Finally, the vibration of the micro mirror die 116 results in an oscillatory movement of the oscillation body 114. Thus, the electrical energy applied to the outer actuator layer 112 is converted to a mechanical energy of the oscillation body 114. In this way, the inner actuators 106 and the outer actuator layer 112 forms the coupled oscillation system.

At step 402A, the method 400 further comprises physically connecting the device wafer 104 with the actuator wafer 102 which comprises bounding said device wafer 104 together with said actuator wafer 102. The device wafer 104 is bonded with the actuator wafer 102 by use of either wafer-level-packaging technique or wafer bonding methods such as anodic bonding or glass frit bonding etc.

In accordance with an embodiment, the oscillation body 114 of each of the inner actuators 106 comprises a wafer-level vacuum encapsulated spring-mirror plate system. The wafer-level vacuum encapsulated spring-mirror plate system reduces the air damping effects and results into high quality factor (Q factor) of the micromechanical resonator wafer assembly 100A.

In accordance with an embodiment, at step 404, the method 400 further comprises bounding the cap wafer 108 on top of the device wafer 104, said cap wafer 108 comprising at least one optical window. In an implementation, the micromechanical resonator wafer assembly 100A includes the actuator wafer 102, the device wafer 104 and additionally, the cap wafer 108. The cap wafer 108 is placed above the device wafer 104 to form a sealed vacuum cavity for low air damping operation of the oscillation body 114. The cap wafer 108 is bonded on top of the device wafer 104 and the device wafer 104 is bonded on top of the actuator wafer 102 to form a three-level wafer stack such as the micromechanical resonator wafer assembly 200A.

In accordance with an embodiment, the optical window is 3D-shaped. In an implementation, the cap wafer 108 may refer to a three-dimensional (3-D shaped) glass wafer. In such implementation, the optical window is either tilted or has a dome like shape.

In accordance with an embodiment, the method 400 further comprises bounding the spacer wafer 202 between the actuator wafer 204 and the device wafer 104. The spacer wafer 202, the device wafer 104 and the actuator wafer 204 are aligned such that the device wafer 104 is placed above the spacer wafer 202 and the spacer wafer 202 is arranged above the actuator wafer 204. The spacer wafer 202 is bounded with the device wafer 104 and the actuator wafer 204 to form a three-level wafer stack of the micromechanical resonator wafer assembly 200A using wafer bonding methods that may include, but are not limited to anodic bonding, glass frit bonding and the like.

The steps 402 to 404 are only illustrative and other alternatives can also be provided where one or more steps are added, one or more steps are removed, or one or more steps are provided in a different sequence without departing from the scope of the claims herein.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments and/or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the invention, which are, for brevity, described in the context of a single embodiment, may also be provided separately or in any suitable combination or as suitable in any other described embodiment of the disclosure.

1. A micromechanical resonator wafer assembly comprising:
an actuator wafer supporting an outer actuator layer which comprises an oscillating part configured to be driven by an electrical drive signal,
a device wafer mounted on top of the actuator wafer, comprising a plurality of inner actuators, each of said inner actuators including an oscillation body configured to oscillate about one or more axes, the oscillation of the oscillation body having one or more eigenfrequencies,
the device wafer being physically connected to the actuator wafer such that each of the inner actuators forms with the outer actuator layer a coupled oscillation system for excitation of the oscillation body of the respective inner actuator by transfer of energy from the oscillating part to the oscillation body when the oscillating part of the outer actuator layer is activated with a frequency selected to excite resonant or near-resonant oscillation of the oscillation body of the inner actuator.

2. The micromechanical resonator wafer assembly according to claim 1, wherein the device wafer is bounded together with the actuator wafer.

3. The micromechanical resonator wafer assembly according to claim 1, comprising a cap wafer bounded on top of the device wafer and comprising at least one optical window.

4. The micromechanical resonator wafer assembly according to claim 3, wherein the optical window is 3D-shaped.

5. The micromechanical resonator wafer assembly according claim 1, comprising a spacer wafer bounded between the actuator wafer and the device wafer.

6. The micromechanical resonator wafer assembly according to claim 1, wherein each of the inner actuators comprises an internal sensor configured to allow reading out of a position feedback signal of its oscillation body by driving means.

7. The micromechanical resonator wafer assembly according to claim 1, wherein the outer actuator layer is a piezoelectric layer, with patterned metallic electrodes configured to face a corresponding inner actuator in the device wafer and to be connected to a driving part to receive an electrical drive signal.

8. The micromechanical resonator wafer assembly according to claim 7, wherein the outer actuator layer is a stacked piezoelectric structure comprising a bottom layer including one or more bottom patterned electrodes, a piezoelectric layer on top of the bottom layer and a top layer on top of the piezoelectric layer and including one or more top patterned electrodes.

9. The micromechanical resonator wafer assembly according to claim 6, wherein the outer actuator layer comprises a sequence of alternating piezoelectric layers and passive layers, with at least one piezoelectric layer and at least one passive layer.

10. The micromechanical resonator wafer assembly according to claim 1, wherein the actuator wafer comprises a ceramic substrate with patterned piezoelectric areas.

11. The micromechanical resonator wafer assembly according to claim 10, wherein the patterned piezoelectric areas are stacked piezoelectric areas comprising a bottom electrode, a piezoelectric layer on top of the bottom electrode, and a top electrode on top of the piezoelectric layer.

12. The micromechanical resonator wafer assembly according to claim 1, wherein the oscillation body of each of the inner actuators comprises a wafer-level vacuum encapsulated spring-mirror plate system.

13. A light engine for laser scanning or a laser projection system, comprising at least one micromechanical resonator assembly obtained by singulation of a micromechanical resonator wafer assembly according to claim 1.

14. A laser projection or scanning system comprising a light engine according to claim 13, such as AR or VR glasses or an AR or VR helmet, or a Lidar system.

15. A method of fabricating a micromechanical resonator wafer assembly comprising an actuator wafer, supporting an outer actuator layer which comprises an oscillating part configured to be driven by an electrical drive signal, a device wafer mounted on top of the actuator wafer, comprising a plurality of inner actuators, each of which including an oscillation body configured to oscillate about one or more axis, the method comprising physically connecting the device wafer together with the actuator wafer such that each of the inner actuators forms with the outer actuator layer a coupled oscillation system for excitation of the corresponding oscillation body by transfer of energy from the oscillating part to said corresponding oscillation body.

16. The method according to claim 15, wherein physically connecting the device wafer with the actuator wafer comprises bounding said device wafer together with said actuator wafer.

17. The method according to a claim 15, comprising bounding a cap wafer on top of the device wafer, said cap wafer comprising at least one optical window.

18. The method according to claim 17, wherein the optical window is 3D-shaped.

19. The method according to claim 15, comprising bounding a spacer wafer between the actuator wafer and the device wafer.

20. The method according to claim 15, wherein the oscillation body of each of the inner actuators comprises a wafer-level vacuum encapsulated spring-mirror plate system.
